(19) United States
(12) Patent Application Publication
(10) Pub. No.: US 2025/0126811 A1
(43) Pub. Date: Apr. 17, 2025

(54) SEMICONDUCTOR DEVICE AND METHOD OF MANUFACTURING THEREOF

(71) Applicant: AP MEMORY TECHNOLOGY CORPORATION, HSINCHU COUNTY (TW)

(72) Inventors: WEN-LIANG CHEN, HSINCHU COUNTY (TW); CHIN-HUNG LIU, HSINCHU COUNTY (TW); KEE-WEI CHUNG, HSINCHU COUNTY (TW); RU-YI CAI, HSINCHU COUNTY (TW); HSIN-NAN CHUEH, HSINCHU COUNTY (TW)

(21) Appl. No.: 18/777,444

(22) Filed: Jul. 18, 2024

Related U.S. Application Data
(60) Provisional application No. 63/589,665, filed on Oct. 12, 2023.

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80895; H01L 2224/80896; H01L 2924/1431; H01L 2924/1436

(57) ABSTRACT

The present application discloses a semiconductor device. The semiconductor device includes a memory stacking pair. The memory stacking pair includes a first memory semiconductor structure and a second memory semiconductor structure. The first memory semiconductor structure has a first front side and a first back side opposite to the first front side. The second memory semiconductor structure has a second front side and a second back side opposite to the second front side. The first memory semiconductor structure is bonded to the second memory semiconductor structure, and the first front side of the first memory semiconductor structure is proximal to the second front side of the second memory semiconductor structure, and the first back side is distal to the second back side.

### CROSS REFERENCE

This application claims the benefit of prior-filed provisional application No. 63/589,665, filed on Oct. 12, 2023, which is incorporated by reference in its entirety.

### TECHNICAL FIELD

The present disclosure relates to a semiconductor device, and more particularly, to a semiconductor device having a memory stacking structure.

### DISCUSSION OF THE BACKGROUND

As artificial intelligence (AI) has become increasingly popular and has been widely adopted in many applications in our daily lives, the demand for high-performance computing (HPC) has also grown fast in the market. Since the AI models usually require complicated computations upon a large amounts of data, the processing speed of AI is not only limited by hardware computing power but also by memory bandwidth (i.e., the speed of data access). To meet the demands of high memory bandwidth for HPC, heterogeneous wafer-on-wafer (WoW) stacking technique has been implemented to stack multiple memory wafers on a logic wafer. The WoW stacking structure allows the logic die to access more memories in closer proximity, resulting higher data bandwidths. However, since the stacking process may impact the yield rate, improvement of the manufacturing process of the heterogeneous structure has become a critical issue to be solved in this field.

### SUMMARY

One aspect of the present disclosure provides a semiconductor device. The semiconductor device includes a memory stacking pair. The memory stacking pair includes a first memory semiconductor structure and a second memory semiconductor structure. The first memory semiconductor structure has a first front side and a first back side opposite to the first front side, and the second memory semiconductor structure has a second front side and a second back side opposite to the second front side. The first memory semiconductor structure is bonded to the second memory semiconductor structure, and the first front side of the first memory semiconductor structure is proximal to the second front side of the second memory semiconductor structure, and the first back side is distal to the second back side.

Another aspect of the present disclosure provides method of manufacturing a semiconductor device. The method includes providing a first memory semiconductor structure having a first front side and a first back side, providing a second memory semiconductor structure having a second front side and a second back side, bonding the first memory semiconductor structure to the second memory semiconductor structure to form a first memory stacking pair, wherein the first front side of the first memory semiconductor structure is proximal to the second front side of the second memory semiconductor structure.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 shows a semiconductor structure according to one comparative embodiment of the present disclosure.

FIGS. 2A to 2H show cross-sectional view or side view of one or more stages for manufacturing the semiconductor structure in FIG. 1.

FIG. 3 shows a semiconductor device according to one embodiment of the present disclosure.

FIG. 4 shows a semiconductor device according to another embodiment of the present disclosure.

FIG. 5 shows a semiconductor device according to another embodiment of the present disclosure.

FIG. 6 shows a flow chart of a method for manufacturing the semiconductor device in FIG. 5 according to one embodiment of the present disclosure.

FIGS. 7A to 7F show cross-sectional view of one or more stages for manufacturing the semiconductor device in FIG. 5 according to one embodiment of the present disclosure.

FIG. 8 shows a semiconductor device according to another embodiment of the present disclosure.

FIGS. 9A to 9C show cross-sectional view of one or more stages for manufacturing the semiconductor device in FIG. 8 according to one embodiment of the present disclosure.

FIG. 10 shows a semiconductor device according to another embodiment of the present disclosure.

FIGS. 11A to 11C show cross-sectional view of one or more stages for manufacturing the semiconductor device in FIG. 10 according to one embodiment of the present disclosure.

FIG. 12 shows a semiconductor device according to another embodiment of the present disclosure.

FIGS. 13A to 13C show cross-sectional view of one or more stages for manufacturing the semiconductor device in FIG. 12 according to one embodiment of the present disclosure.

### DETAILED DESCRIPTION

The following description accompanies drawings, which are incorporated in and constitute a part of this specification, and which illustrate embodiments of the disclosure, but the disclosure is not limited to the embodiments. In addition, the following embodiments can be properly integrated to complete another embodiment.

References to “one embodiment,” “an embodiment,” “exemplary embodiment,” “other embodiments,” “another embodiment,” etc. indicate that the embodiment(s) of the disclosure so described may include a particular feature, structure, or characteristic, but not every embodiment necessarily includes the particular feature, structure, or characteristic. Further, repeated use of the phrase “in the embodiment” does not necessarily refer to the same embodiment, although it may.

In order to make the present disclosure completely comprehensible, detailed steps and structures are provided in the following description. Obviously, implementation of the present disclosure does not limit special details known by persons skilled in the art. In addition, known structures and steps are not described in detail, so as not to unnecessarily limit the present disclosure. Preferred embodiments of the present disclosure will be described below in detail. However, in addition to the detailed description, the present disclosure may also be widely implemented in other embodiments. The scope of the present disclosure is not limited to the detailed description, and is defined by the claims.

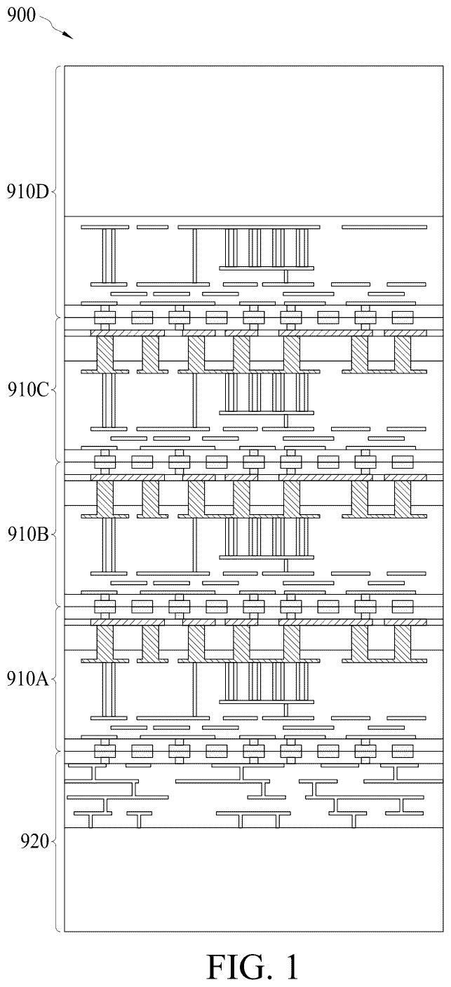

FIG. 1 shows a semiconductor structure 900 with heterogeneous integration according to one comparative embodiment of the present disclosure. The semiconductor structure 900 includes memory semiconductor structures 910A, 910B, 910C, and 910D, and a logic semiconductor structure 920. As shown in FIG. 1, the memory semiconductor structures 910A, 910B, 910C, and 910D are stacked sequentially on the logic semiconductor structure 920.

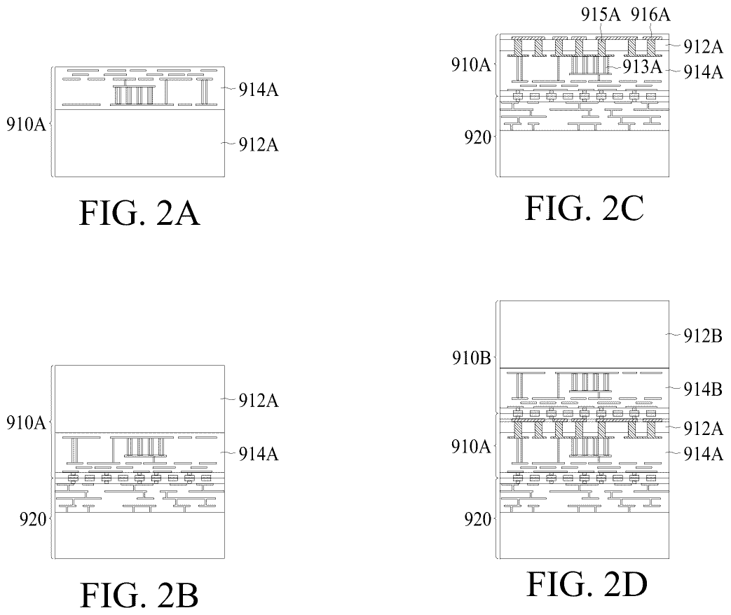

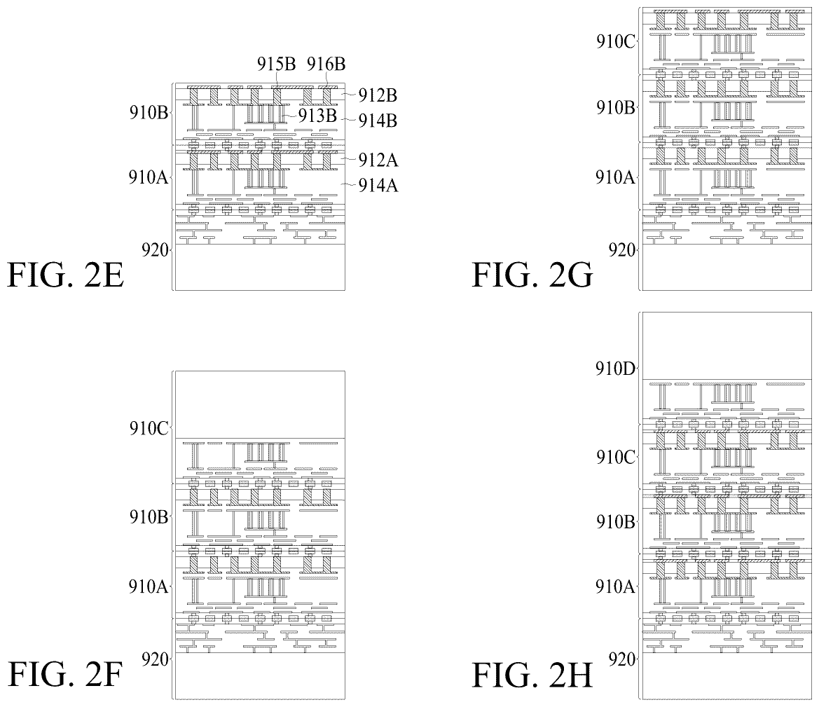

FIGS. 2A to 2H show cross-sectional view or side view of one or more stages for manufacturing the semiconductor structure 900 in FIG. 1 according to a comparative embodiment of the present disclosure.

In FIG. 2A, the memory semiconductor structure 910A is provided. As shown in FIG. 2A, the memory semiconductor structure 910A includes a substrate 912A and a semiconductor dielectric 914A formed over the substrate 912A.

In FIG. 2B, the memory semiconductor structure 910A is bonded to the logic semiconductor structure 920 with a front side of the memory semiconductor structure 910A (i.e., the side proximal to the semiconductor dielectric 914A, in other words, the side distal to the substrate 912A) facing the logic semiconductor structure 920.

In FIG. 2C, the substrate 912A is thinned so as to form through silicon vias (TSVs) 915A within the substrate 912A. In addition, a redistribution layer (RDL) 916A is formed on the substrate 912A. The RDL 916A is coupled to the interconnect structures 913A formed in the semiconductor dielectric 914A through the TSVs 915A.

In FIG. 2D, the memory semiconductor structure 910B is bonded to the memory semiconductor structure 910A with a front side of the memory semiconductor structure 910B (i.e., the side proximal to the semiconductor dielectric 914B, in other words, the side distal to the substrate 912B) facing a back side of the memory semiconductor structure 910A (i.e., the side proximal to the substrate 912A). In FIG. 2E, the substrate 912B of the second memory semiconductor structure 910B is thinned, and a RDL 916B is formed on a back side of the memory semiconductor structure 910B (i.e., the side proximal to the substrate 912B) and is couple to the interconnect structures 913B formed in the semiconductor dielectric 914B through the TSVs 915B formed in the substrate 912B.

With similar processes, the memory semiconductor structures 910C and 910D can be stacked on the memory semiconductor structure 910B subsequently as shown in FIGS. 2F to 2H. In such case, each memory semiconductor structure is bonded to another with its front side facing a back side of the other memory semiconductor structure below.

In addition, during the manufacturing processes shown in FIGS. 2A to 2H, the memory semiconductor structure 910A is bonded to the logic semiconductor structure 920 in an early phase, and thus, the logic semiconductor structure 920 is disposed at the bottom as a base of the stacking structure during all the bonding processes and thinning processes. Therefore, the logic semiconductor structure 920 has to endure the physical stress applied during the bonding processes and thinning processes, such as Chemical-Mechanical-Polishing (CMP) or grinding, which may cause damage to logic semiconductor structure 920 and decrease the yield rate. Specifically, each bonding stage of the memory semiconductor structure may cause the loss of the yield, and if one of the bonding stages suffers the yield loss, the yield of the whole device will be further impacted. Especially, the logic semiconductor structure 920 is complicatedly designed and more costly than the memory semiconductor structures 910A to 910D, the damage of the logic semiconductor structures 920 may increase the total manufacturing cost significantly. For example, the logic semiconductor structure 920 may include one or more processors, such as central processing units (CPU), graphic processing units (GPUs), controller, or application specific integrated circuit (ASIC). Therefore, the loss of the logic semiconductor structure 920 should be minimized as much as possible. In addition, the logic semiconductor structure can be replaced by an intermediate carrier (e.g., glass carrier) and move the step of the bonding process of the logic semiconductor structure 920 to the later step. But the usage of the intermediate carrier will increase the overall process cost, and the de-bonding process of the intermediate carrier will also induce yield impact. Therefore, the cost and yield loss of entire process should also be concerned.

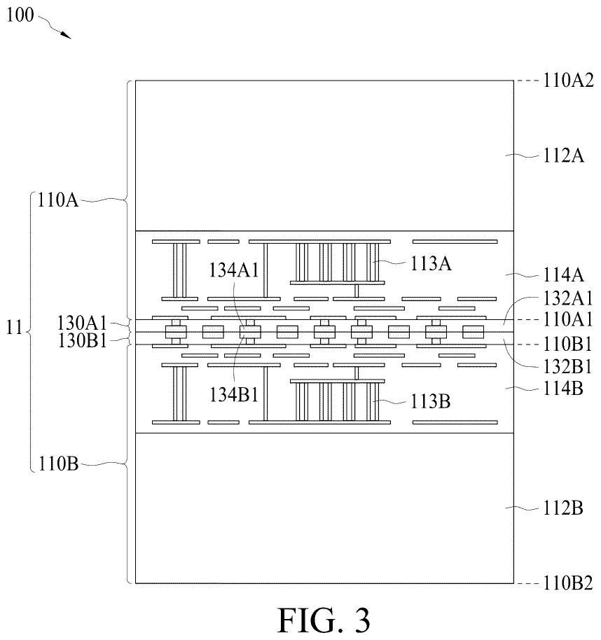

FIG. 3 shows a semiconductor device 100 according to one embodiment of the present disclosure. The semiconductor device 100 includes a memory stacking pair 11. The memory stacking pair 11 includes a memory semiconductor structure 110A and a memory semiconductor structure 110B. The memory semiconductor structure 110A is stacked on the memory semiconductor structure 110B. In some embodiments, the memory semiconductor structures 110A and 110B are Volatile memory (e.g., Dynamic-Random-Access-Memory, DRAM) or Non-volatile memory (e.g., NOR flash or NAND flash memory).

The memory semiconductor structure 110A includes a substrate 112A and a dielectric 114A. In some embodiments, the substrate 112A may include semiconductive material such as silicon, germanium, gallium, glass, or a combination thereof. In some embodiments, the substrate 112A can be a wafer substrate. In some embodiments, the substrate 112A is a silicon substrate. In some embodiments, the substrate 112A is a silicon substrate in a die level.

As shown in FIG. 3, the dielectric 114A is disposed over the substrate 112A. In some embodiments, the dielectric 114A includes dielectric material, such as silicon oxide, silicon nitride, polymer, or the like. In some embodiments, the dielectric 114A includes several dielectrics layers stacking over each other. In some embodiments, the dielectric 114A includes same material or different materials. In some embodiments, the dielectric 114A is interlayer dielectric (ILD) and inter-metal dielectric (IMD).

In some embodiments, the memory semiconductor structure 110A further includes at least one interconnect structure 113A formed within the dielectric 114A. In some embodiments, the interconnect structure 113A is configured to facilitate the electrical routing between devices, such as transistors and capacitors, formed with the active regions (not shown) of the substrate 112A, thereby enabling the formation of desired circuits (e.g., memory cells). For example, the interconnect structure 113A may include metal lines that extend laterally at different levels and metal vias that extend vertically for connecting metal lines at different levels. In some embodiments, the interconnect structure 113A and the dielectric 114A are formed in a back end of line (BEOL) process.

The memory semiconductor structure 110B is configured similar or identical to that of the memory semiconductor structure 110A. For example, the memory semiconductor structure 110B also includes a substrate 112B, a dielectric 114B, and at least one interconnect structure 113B formed within the dielectric 114B. In the present embodiments, the memory semiconductor structure 110A has a front side 110A1 (i.e., in proximal to the dielectric 114A) and a back side 110A2 (i.e., in proximal to the substrate 112A) opposite to the front side 110A1. Also, the memory semiconductor structure 110B has a front side 110B1 (i.e., in proximal to the dielectric 114B) and a back side 110B2 (i.e., in proximal to the substrate 112B) opposite to the front side 110B1. In some embodiments, both the memory semiconductor structures 110A and 110B are DRAMs. In some embodiments, both the memory semiconductor structures 110A and 110B are DRAMs with same capacity or density. In some embodiments, both the memory semiconductor structures 110A and 110B are DRAMs with same capacity and are manufactured by the same process and same reticles.

In the present embodiment, the memory semiconductor structure 110A is bonded to the memory semiconductor structure 110B through a bonding layer 130A1 formed on the front side 110A1 of the memory semiconductor structure 110A and a bonding layer 130B1 formed on the front side 110B1 of the memory semiconductor structure 110B. As shown in FIG. 3, the bonding layer 130A1 includes a bonding dielectric 132A1 and at least one bonding pad 134A1. In some embodiments, the bonding pad 134A1 is surrounded by and at least partially exposed through the bonding dielectric 132A1. In some embodiments, the bonding pad 134A1 extends through the bonding dielectric 132A1 to electrically connect to the interconnect structure 113A formed in the dielectric 114A. Similarly, the bonding layer 130B1 include the bonding dielectric 132B1 and at least one bonding pad 134B1 formed therein.

In some embodiments, the bonding layer 130A1 and the bonding layer 130B1 are bonded through a hybrid bonding process. In some embodiments, the bonding pad 134A1 and the bonding pad 134B1 are aligned, so as to facilitate the hybrid bonding process. Specifically, the hybrid bonding process includes bonding the bonding dielectric 132A1 in the bonding layer 130A1 with the bonding dielectric 132B1 in the bonding layer 130B1 (dielectric-to-dielectric), and bonding the bonding pad 134A1 in the bonding layer 130A1 to the bonding pad 134B1 in the bonding layer 130B1 (metal-to-metal). For example, during the hybrid bonding process, the initial bond occurs at the dielectric-to-dielectric interface at room temperature under atmospheric conditions. The copper metal-to-metal connection is formed via annealing and metal diffusion. However, the present disclosure is not limited thereto. Other capable bonding flow can also be adopted to facilitate the hybrid bonding process.

In the present embodiment, the memory semiconductor structure 110A is bonded to the memory semiconductor structure 110B with the front side 110A1 of the memory semiconductor structure 110A being proximal to the front side 110B1 of the memory semiconductor structure 110B. That is, the memory semiconductor structure 110A is bonded to the memory semiconductor structure 110B in a front-to-front (i.e., face-to-face) manner, and the back side 110A2 of the memory semiconductor structure 110A is distal to the back side 110B2 of the memory semiconductor structure 110B.

In some embodiments, the memory semiconductor structures that are used to form memory stacking pair can have circuitry layouts that are mirror images to each other. For example, the circuitry layout of the memory semiconductor structure 110A can be a mirror image of the circuitry layout of the memory semiconductor structure 110B. In such case, locations of input/output ports of the memory semiconductor structure 110A can be aligned with locations of the input/output ports of the memory semiconductor structure 110B when the two are stacked in the front-to-front manner as shown in FIG. 3. As a result, the placement of the bonding pads 134A1 and 134B1 can be simplified. However, the present disclosure is not limited thereto. In some embodiments, the circuitry layout of the memory semiconductor structure 110A can be mirror symmetric along a central symmetry surface cutting through the dielectric 114, and the circuitry layout of the memory semiconductor structure 110B can be identical to that of the memory semiconductor structure 110A, so that the locations of input/output ports of the memory semiconductor structure 110A can still be aligned with the locations of the input/output ports of the memory semiconductor structure 110B when the two are stacked in the front-to-front manner. Furthermore, in such case, the memory semiconductor structure 110A and the memory semiconductor structure 110B can be manufactured by the same reticles, thereby further reducing the manufacturing cost and the complexity of bonding process.

In some embodiments, the memory stacking pair 11 can be used as a stacking unit to stack with a logic semiconductor structure so that the logic semiconductor structure can be bonded in a later or last stage, thereby reducing steps of the bonding process during the integration with the logic semiconductor structure and protecting the costly logic semiconductor structure from being damaged during the manufacturing process.

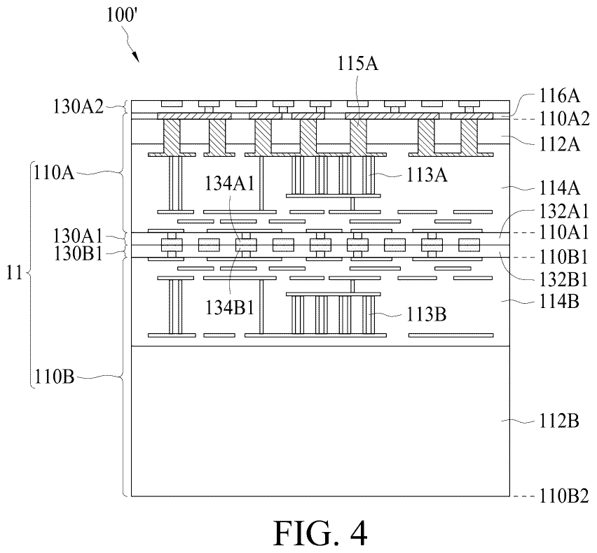

FIG. 4 shows a semiconductor device 100′ according to one embodiment of the present disclosure. The semiconductor device 100′ can be produced by thinning the backside substrate 112A of the semiconductor 100 and forming a RDL 116A and a bonding layer 130A2 thereof so as to allow the logic semiconductor structure to be stacked on the memory stacking pair 11. Specifically, the substrate 112A of the semiconductor device 100′ at the back side 110A2 of the memory semiconductor structure 110A can be thinned so as to form TSVs 115A within the substrate 112A. Also, the RDL 116A can be formed on the substrate 112A so as to couple to the interconnect structures 113A through the TSVs 115A, and the bonding layer 130A2 for bonding with the logic semiconductor structure. The RDL 116A and the bonding layer 130A2 is formed proximal to the back side 110A2 of the memory semiconductor structure 110A, and distal to the front side 110A1 of the memory semiconductor structure 110A.

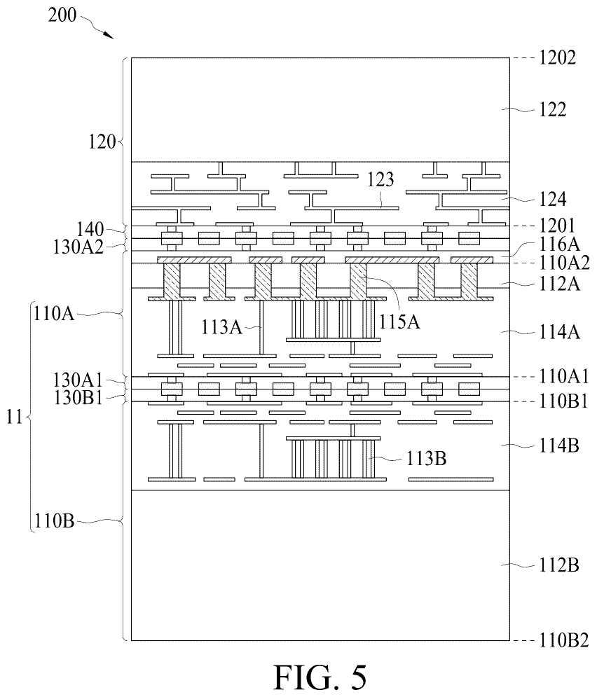

FIG. 5 shows a semiconductor device 200 according to one embodiment of the present disclosure. The semiconductor device 200 includes the memory stacking pair 11 and a logic semiconductor structure 120 stacked on the memory stacking pair 11. The logic semiconductor structure 120 includes a substrate 122, a dielectric 124 formed over the substrate 122, and at least one interconnect structure 123 formed within the dielectric 124.

In the present embodiment, the logic semiconductor structure 120 has a front side 1201 and a back side 1202 opposite to the front side 1201. The front side 1201 is in proximal to the dielectric 124 and is distal to the substrate 122. The logic semiconductor structure 120 is bonded to the memory stacking pair 11 with a bonding layer 140 formed on the front side 1201 of the logic semiconductor structure 120 and a bonding layer 130A2 formed on the back side 110A2 of the memory semiconductor structure 110A. Consequently, the logic semiconductor structure 120 is bonded to the memory stacking pair 11 to form a heterogeneous integration with the front side 1201 of the logic semiconductor structure 120 being proximal to the back side 110A2 of the memory semiconductor structure 110A. In such case, the logic semiconductor structure 120 can be stacked on the memory stacking pair 11 after the memory stacking pair 11 is formed, thereby protecting the logic semiconductor structure 120 from being damaged during the stacking process and thinning process of the memory stacking pair 11. In some embodiments, the memory stacking pair 11 may be provided with the reliable yield, and the logic semiconductor structure 120 may be integrated with the memory stacking pair through one bonding process. As a result, the possible yield impact of bonding process can be reduced.

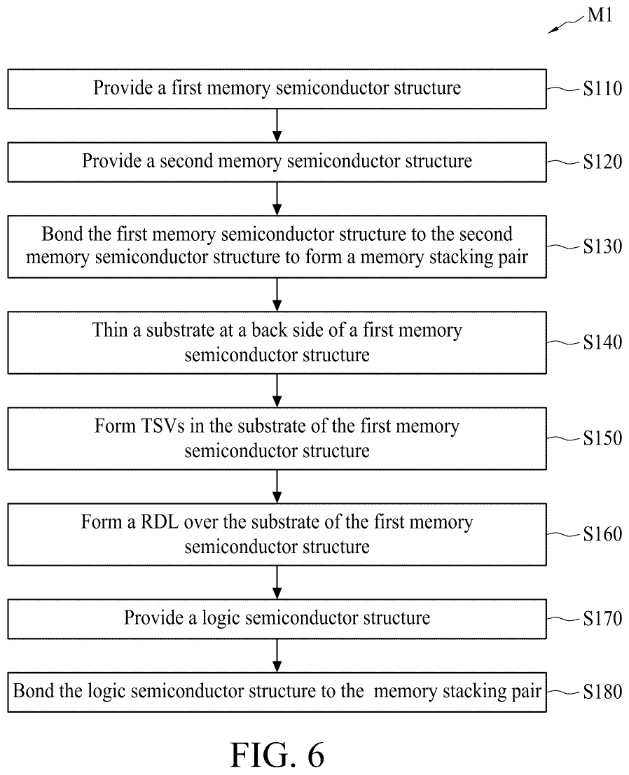

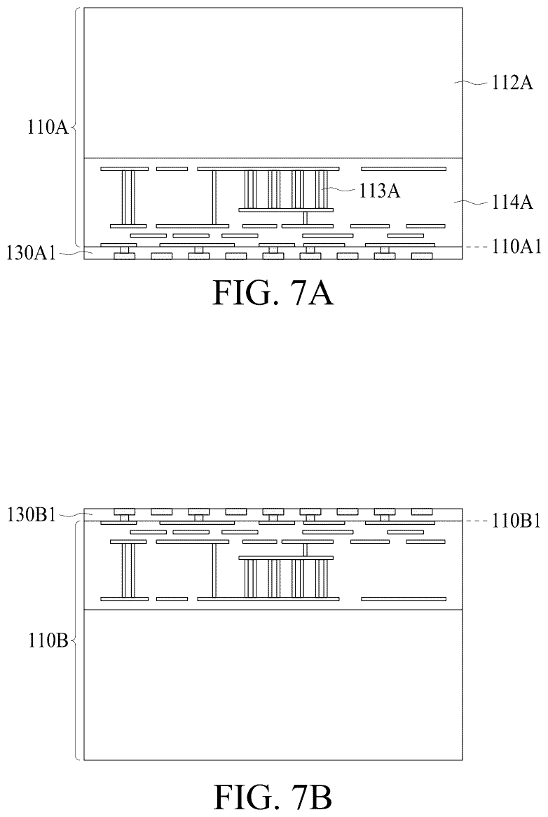

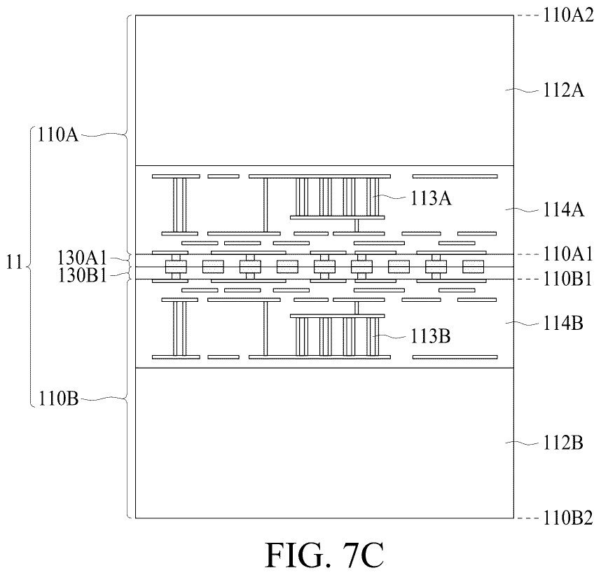

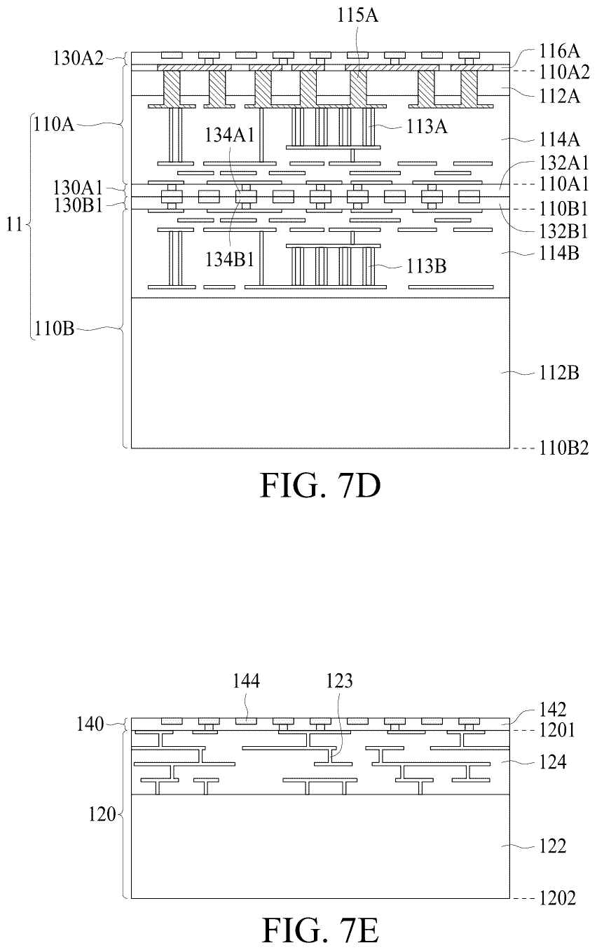

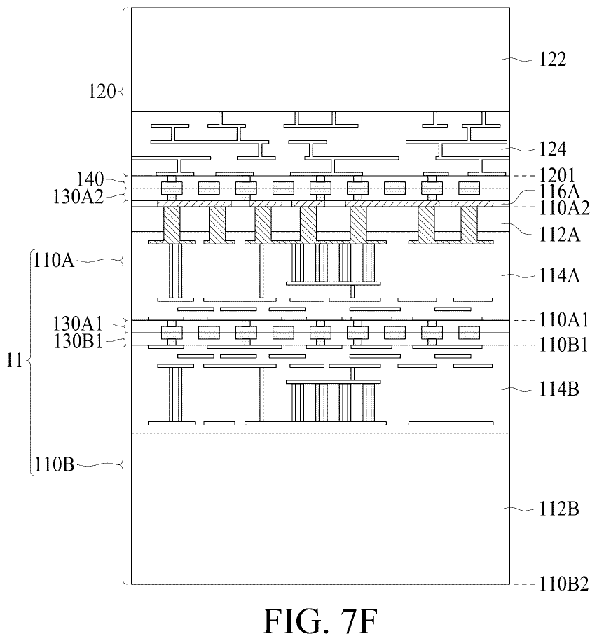

FIG. 6 shows a flow chart of a method M1 for manufacturing the semiconductor device 200 according to one embodiment of the present disclosure. The method M1 includes steps S110 to S180. FIGS. 7A to 7F show cross-sectional view of one or more stages of the method M1 for manufacturing the semiconductor device 200 according to one embodiment of the present disclosure.

In steps S110 and S120, the memory semiconductor structure 110A and the memory semiconductor structure 110B are provided. In addition, as shown in FIGS. 7A and 7B, the bonding layers 130A1 and 130B1 can be formed on the front side 110A1 of the memory semiconductor structure 110A and the front side 110B1 of the memory semiconductor structure 110B respectively so as to facilitate the hybrid bonding process in step S130.

In step S130, the memory semiconductor structure 110A is bonded to the memory semiconductor structure 110B by hybrid bonding the bonding layer 130A1 to the bonding layer 130B1 as shown in FIG. 7C. Consequently, the memory stacking pair 11 is formed with the front side 110A1 of the memory semiconductor structure 110A being proximal to the front side 110B1 of the memory semiconductor structure 110B, which is in a front-to-front (i.e., face-to-face) manner. In some embodiments, the memory semiconductor structure 110A and the memory semiconductor structure 110B are provided as wafers, and the memory stacking pair 11 exhibit a wafer-on-wafer (WoW) structure.

In step S140, the substrate 112A at the back side 110A2 of the memory semiconductor structure 110A is thinned so as to form TSVs 115A within the substrate 112A in step S150. In addition, an RDL 116A is formed on the substrate 112A and is coupled to the interconnect structures 113A through the TSVs 115A in step S160 as shown in FIG. 7D.

In step S170, the logic semiconductor structure 120 is provided. As shown in FIG. 7E, the logic semiconductor structure 120 includes the substrate 122, the dielectric 124, and at least one interconnect structure 123 formed in the dielectric 124. Furthermore, a bonding layer 140 including a bonding dielectric 142 and at least one bonding pad 144 is formed on the front side 1201 of the logic semiconductor structure 120. In some embodiments, the bonding pad 144 is surrounded by and at least partially exposed through the bonding dielectric 142. In some embodiments, the bonding pad 144 extends through the bonding dielectric 142 to electrically connect to the interconnect structure 123 formed in the dielectric 124.

In step S180, the logic semiconductor structure 120 is bonded to the memory stacking pair 11 by hybrid bonding the bonding layer 140 and the bonding layer 130A2, so that the front side 1201 of the logic semiconductor structure 120 is proximal to the back side 110A2 of the memory semiconductor structure 110A as shown in FIG. 7F.

With the method M1, the memory semiconductor structures 110A and 110B can be bonded as a memory stacking pair 11 first, and the logic semiconductor structure 120 can be bonded to the memory stacking pair 11 in a subsequent step; therefore, the logic semiconductor structure 120 can be free from enduring the physical stress caused during the bonding process of the memory stacking pair 11. Furthermore, the method M1 can be performed without requiring any intermediate carrier, and thus, defects and costs brought by the carrier can also be avoided. As a result, the semiconductor device 200 can be manufactured with a lower cost and a higher yield rate.

In some embodiments, the memory semiconductor structures 110A, 110B, and the logic semiconductor structure 120 can be provided as wafers, and the semiconductor device 200 may refer to the WOW structure of the memory semiconductor structures 110A and 110B and the logic semiconductor structure 120. However, the present disclosure is not limited thereto. In some embodiments, the WOW structure shown in FIG. 7F may further be sawed to form a plurality of stacking dies and the semiconductor device 200 may refer to the stacking dies that singulated from the WoW structure. In such case, the memory semiconductor structures 110A, 110B and the logic semiconductor structure 120 can refer as the memory dies and the logic dies that are stacked. In some embodiments, the logic semiconductor structure 120 can refer to wafer, and the stacks of the memory semiconductor structures 110A and 110B can refer to stacking chips, and the semiconductor structure may be referred as Chip-on-wafer (CoW) structure.

In some embodiments, the processes shown in FIG. 7A to 7F can be adopted to form a semiconductor device that includes more memory semiconductor structures while ensuring the logic semiconductor structure to be bonded in a later stage so as to reduce the yield impact and entire process cost.

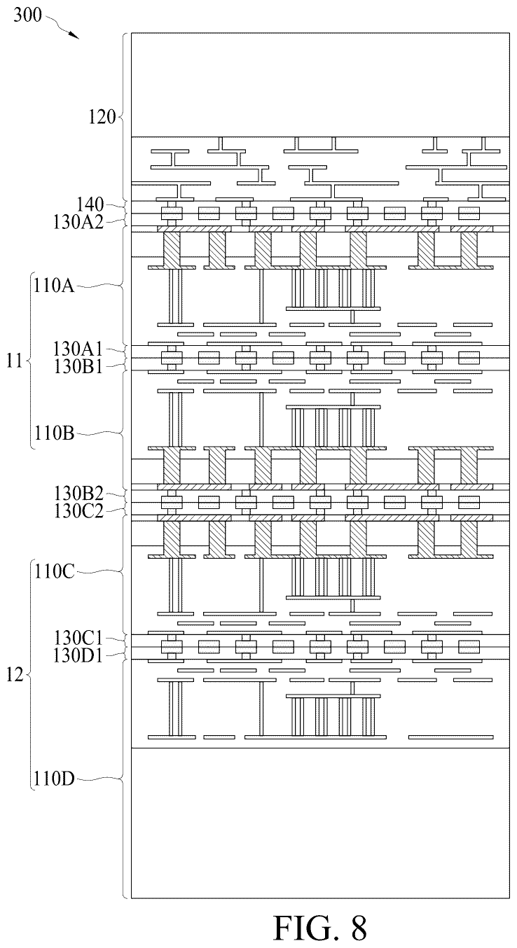

FIG. 8 shows a semiconductor device 300 according to one embodiment of the present disclosure. The semiconductor device 300 is different from the semiconductor device 200 in that the semiconductor device 300 further includes another memory stacking pair 12. The memory stacking pair 12 includes a memory semiconductor structure 110C and a memory semiconductor structure 110D. In some embodiments, the memory semiconductor structure 110C can be stacked on the memory semiconductor structure 110D by similar processes shown in FIGS. 7A to 7C.

Furthermore, in some embodiments, the logic semiconductor structure 120 can be stacked on the memory stacking pair 11 after the memory stacking pair 11 is stacked on the memory stacking pair 12. That is, the logic semiconductor structure 120 can be stacked in a later stage in the manufacturing process of the semiconductor device 300.

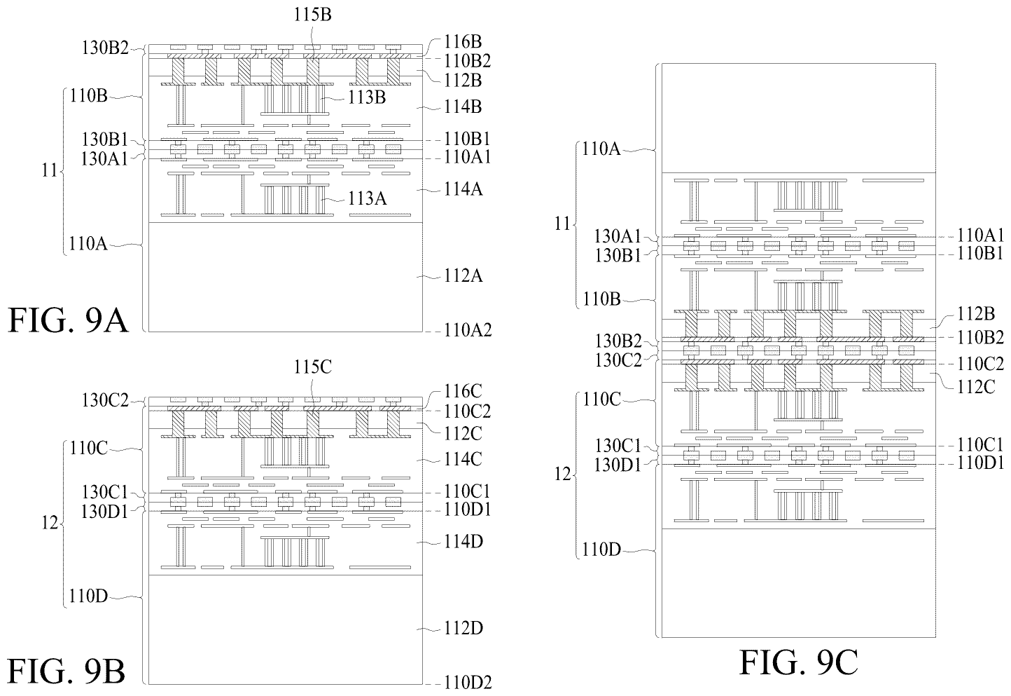

FIGS. 9A to 9C show cross-sectional view of one or more stages for manufacturing the semiconductor device 300 according to one embodiment of the present disclosure. As shown in FIG. 9A, the memory stacking pair 11 can be formed by stacking the memory semiconductor structure 110B on the memory semiconductor structure 110A. In addition, as shown in FIG. 9A, the substrate 112B at the back side 110B2 of the memory semiconductor structure 110B is thinned so as to form the TSVs 115B in the substrate 112B, and the RDL 116B is formed over the substrate 112B. The bonding layer 130B2 is formed on the RDL 116B over the substrate 112B so as to facilitate the subsequent bonding process with the memory stacking pair 12. In some embodiments, the memory stacking pair 11 shown in FIG. 9A can be formed by processes similar to those shown in FIGS. 7A to 7D.

In FIG. 9B, the memory stacking pair 12 can be formed by stacking the memory semiconductor structure 110C on the memory semiconductor structure 110D. In some embodiments, the memory stacking pair 12 can be formed by processes similar to those shown in FIGS. 7A to 7D. For example, the memory semiconductor structure 110C including the substrate 112C and dielectric 114C and the memory semiconductor structure 110D including the substrate 112D, and dielectric 114D can be provided. The bonding layer 130C1 is formed on the front side 110C1 of the memory semiconductor structure 110C (i.e., the side proximal to dielectric 114C), and the bonding layer 130D1 is formed on the front side 110D1 of the memory semiconductor structure 110D (i.e., the side proximal to dielectric 114D). As a result, the memory semiconductor structure 110C can be bonded to the memory semiconductor structure 110D through the bonding layers 130C1 and 130D1 with the front side 110C1 of the memory semiconductor structure 110C being proximal to the front side 110D1 of the memory semiconductor structure 110D.

In addition, as shown in FIG. 9B, the substrate 112C at the back side 110C2 of the memory semiconductor structure 110C is thinned so as to form the TSVs 115C, and the RDL 116C is formed over the substrate 112C. The bonding layer 130C2 is formed on the RDL 116C over the substrate 112C.

In FIG. 9C, the memory stacking pair 11 is flipped upside down so as to be bonded to the memory stacking pair 12 by hybrid bonding the bonding layer 130B2 over the substrate 112B of the memory semiconductor structure 110B and the bonding layer 130C2 over the substrate 112C of the memory semiconductor structure 110C. As a result, the memory stacking pair 11 can be stacked on the memory stacking pair 12 with the back side 110B2 of the memory semiconductor structure 110B being proximal to the back side 110C2 of the memory semiconductor structure 110C. In the following steps, the logic semiconductor structure 120 can be bonded to the memory stacking pair 11 by the similar steps described in FIGS. 7D-7F, and the detail steps are not described herein for brevity.

As shown in FIGS. 9A to 9C, the semiconductor device 300 can be manufactured by forming and stacking the memory stacking pairs 11 and 12 first, thereby allowing the logic semiconductor structure 120 to be stacked on the stacked memory stacking pairs 11 and 12 later. Therefore, the logic semiconductor structure 120 can be free from enduring the physical stress caused during the bonding operations and/or thinning operations performed upon the memory semiconductor structures 110A, 110B, 110C, and 110D, and thus, the logic semiconductor structure 120 can be protected and the yield rate can be improved.

In the embodiments shown in FIGS. 5 and 8, the semiconductor devices 200 and 300 both include even numbers of memory semiconductor structures (e.g., two memory semiconductor structures 110A and 110B in the semiconductor device 200, and four memory semiconductor structures 110A, 110B, 110C, and 110D in the semiconductor device 300), so that either one of the memory semiconductor structures can be stacked as a memory stacking pair first, and then the memory stacking pairs can be stacked on top of each other, allowing the logic semiconductor structure 120 to be stacked in a later stage, thereby protecting the logic semiconductor structure 120 from being damaged during the manufacturing processes of the semiconductor devices 200 and 300 without utilizing any carrier. The same principles can be applied for manufacturing other semiconductor devices that include even number (e.g., 8, 10, or 12) of memory semiconductor structures, so as to stack the logic semiconductor structure in a later stage. In other words, the semiconductor device comprises N memory stacking pairs (N≥1), and each of the N memory stacking pairs comprises two memory semiconductor structure which are stacked in front-to-front (i.e., face-to-face) manner.

In some embodiments, when the semiconductor structure includes N memory stacking pairs and N≥3, semiconductor structure can be formed by stacking each two memory stacking pairs, and then stacking the stacked memory stacking pairs. For example, if N=5, then the semiconductor structure can be formed by stacking two memory stacking pairs, stacking another two memory stacking pairs, stacking the two stacked memory stacking pairs, and then stacking the last memory stacking pairs on the stacked memory stacking pairs that include four memory stacking pairs. However, the present disclosure is not limited thereto. In some other embodiments, the semiconductor structure including 5 memory stacking pairs can be formed by stacking two memory stacking pairs first, and stacked the rest three memory stacking pairs on top of the stacked memory stacking pairs one by one. Alternatively, the semiconductor structure can also be formed by stacking two memory stacking pairs, stacking another two memory stacking pairs, stacking the rest one memory stacking pair on one of the stacked memory stacking pairs, and then stacking the stacked memory stacking pairs including two memory stacking pairs with the stacked memory stacking pairs including three memory stacking pairs. It should also be noted that, in the aforementioned embodiments, each memory stacking pair includes two memory semiconductor structures stacked in front-to-front manner.

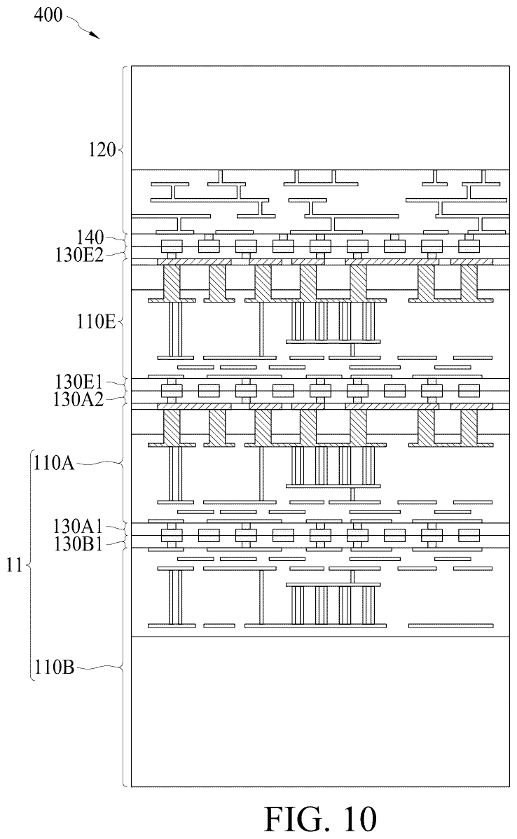

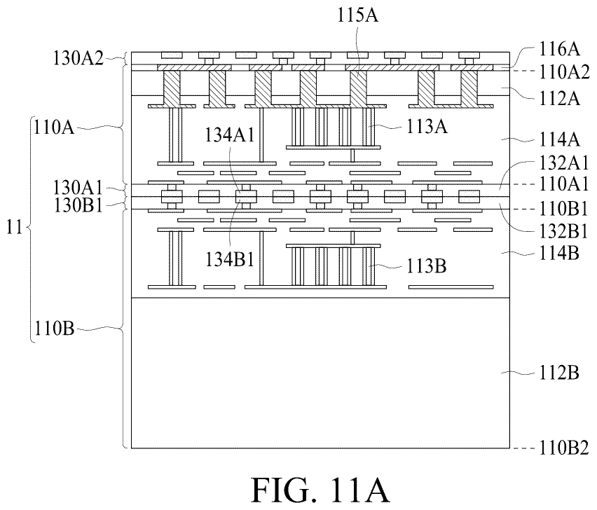

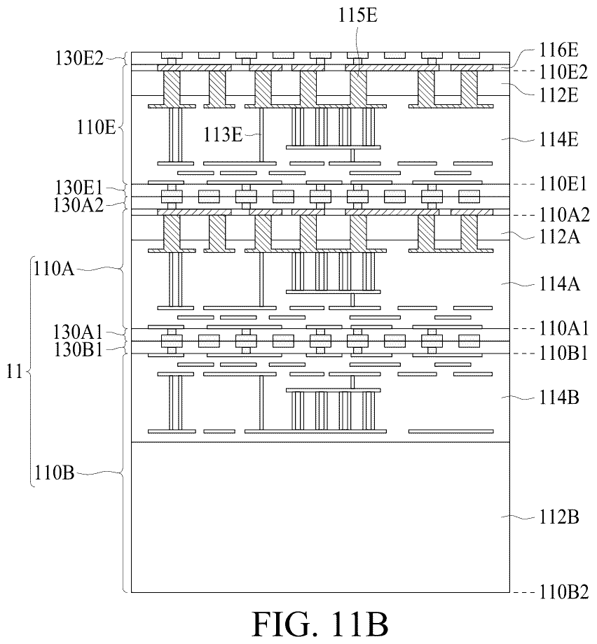

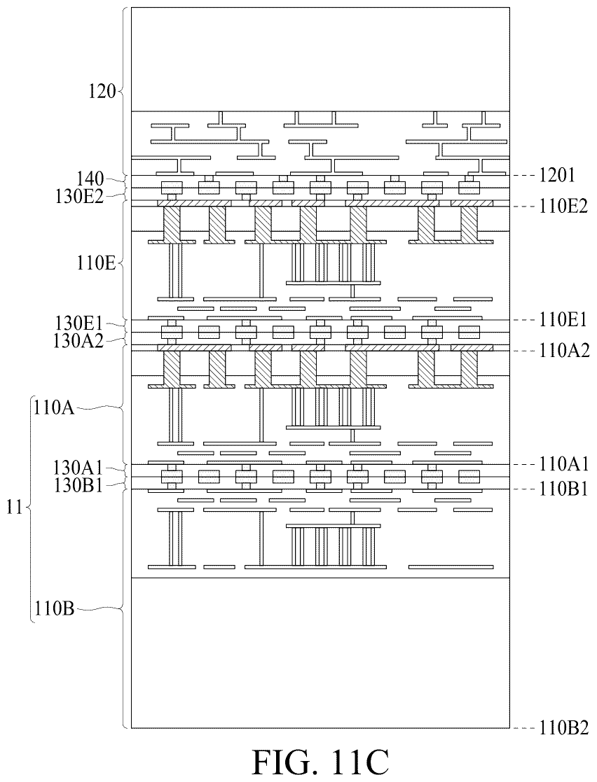

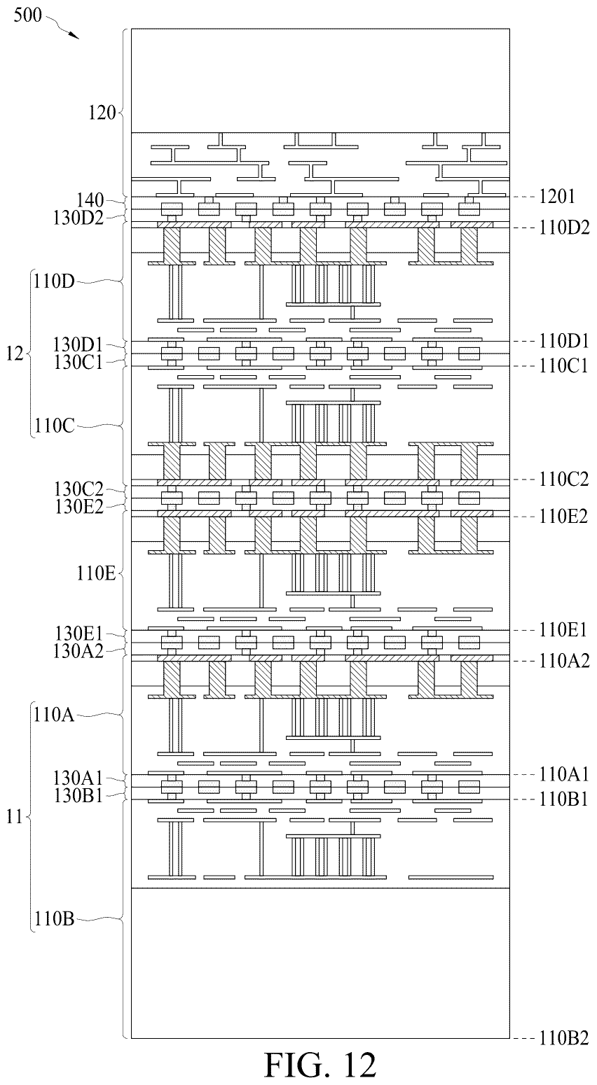

In some embodiments, the semiconductor device including odd number of memory semiconductor structures may also allow the logic semiconductor structure to be stacked in a later stage without requiring any carrier. FIG. 10 shows a semiconductor device 400 according to one embodiment of the present disclosure. The semiconductor device 400 includes memory semiconductor structures 110A, 110B, 110E, and the logic semiconductor structure 120. FIGS. 11A to 11C show cross-sectional view of one or more stages for manufacturing the semiconductor device 400 according to one embodiment of the present disclosure.

In FIG. 11A, the memory semiconductor structure 110A is bonded to the memory semiconductor structure 110B with the substrate 112A at the back side 110A2 of the memory semiconductor structure 110A being thinned and the RDL 116A and the bonding layer 130A2 being formed thereon. In some embodiments, the memory semiconductor structure 110A can be stacked on the memory semiconductor structure 110B to form the memory stacking pair 11 according to the processes shown in FIGS. 7A to 7D.

In FIG. 11B, the memory semiconductor structure 110E is bonded to the memory stacking pair 11 by hybrid bonding the bonding layer 130A2 at the back side 110A2 of the memory semiconductor structure 110A and a bonding layer 130E1 formed on the front side 110E1 of the memory semiconductor structure 110E. That is, the front side 110E1 of the memory semiconductor structure 110E is proximal to the back side 110A2 of the memory semiconductor structure 110A. In addition, as shown in FIG. 11B, the substrate 112E is thinned so as to form the TSVs 115E therein, and the RDL 116E and another bonding layer 130E2 can be formed over the substrate 112E sequentially. The RDL 116E can be coupled to the interconnect structure 113E formed in the dielectric 114E through the TSVs 115E.

In FIG. 11C, the logic semiconductor structure 120 is stacked on the memory semiconductor structure 110E that has been stacked on the memory stacking pair 11. In the present embodiments, the logic semiconductor structure 120 can be bonded to the memory semiconductor structure 110E by hybrid bonding the bonding layer 130E2 formed on the back side 110E2 of the memory semiconductor structure 110E and the bonding layer 140 formed on the front side 1201 of the logic semiconductor structure 120, so that the front side 1201 of the logic semiconductor structure 120 is proximal to the back side 110E2 of the memory semiconductor structure 110E.

Consequently, the logic semiconductor structure 120 can be stacked on the memory semiconductor structures 110A, 110B, and 110E in a later stage of the manufacturing process, thereby protecting the logic semiconductor structure 120 from being damaged during the stacking and thinning processes of the memory semiconductor structures 110A, 110B, and 110E.

In some embodiments, semiconductor devices including odd number of memory semiconductor structures, such as 5, 7, and 9, may also be manufactured by following processes similar to those shown in FIGS. 11A to 11C. For example, each two of the memory semiconductor structures can be stacked to form a memory stacking pair first, then the rest single memory semiconductor structure can be stacked on the memory stacking pairs that have been stacked, and finally the logic semiconductor structure can be stacked on the single memory semiconductor structure. Since the logic semiconductor structure can be stacked in a later stage, the logic semiconductor structure 120 can be protected from being damaged during the stacking and thinning processes of the memory semiconductor structures.

In some embodiments, the single memory semiconductor structure may be stacked in any position in between memory stacking pairs. FIG. 12 shows a semiconductor device 500 according to another embodiment of the present disclosure. The semiconductor device 500 includes five memory semiconductor structures 110A, 110B, 110C, 110D and 110E with the memory semiconductor structures 110A and 110B being stacked as the memory stacking pair 11, the memory semiconductor structures 110C and 110D being stacked as the memory stacking pair 12, and the memory semiconductor structure 110E being disposed between the memory stacking pair 11 and the memory stacking pair 12.

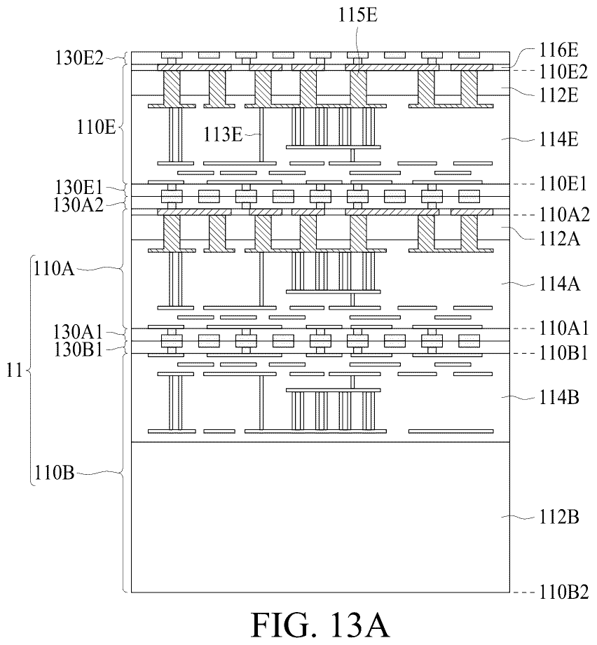

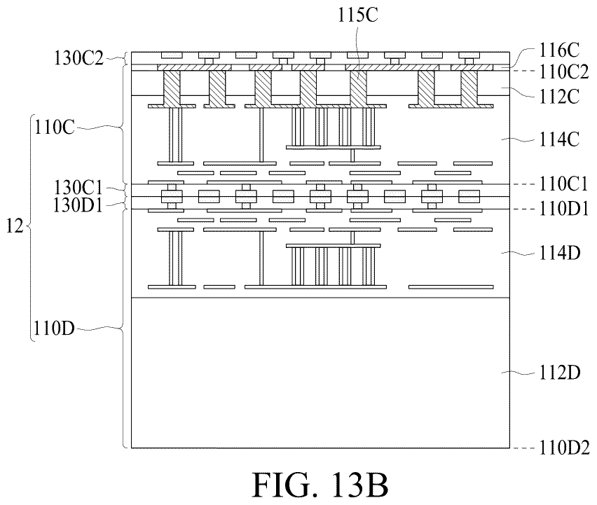

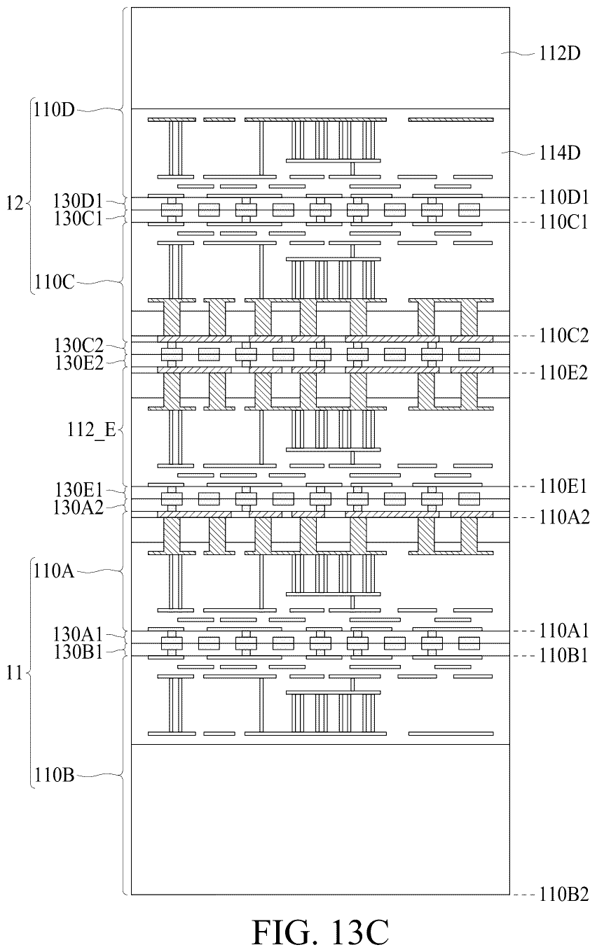

FIGS. 13A to 13C show cross-sectional view of one or more stages for manufacturing the semiconductor device 500 according to one embodiment of the present disclosure.

In FIG. 13A, the memory semiconductor structures 110A and 110B are bonded so as to form the memory stacking pair 11, and the memory semiconductor structures 110E is bonded to the memory stacking pair 11. In some embodiments, the memory semiconductor structures 110A, 110B, and 110E can be stacked according to the processes shown in FIGS. 11A and 11B, and the front side 110E1 of the memory semiconductor structure 110E would be proximal to the back side 110A2 of the memory semiconductor structure 110A.

In FIG. 13B, the memory semiconductor structures 110C and 110D are bonded to form the memory stacking pair 12 with the front side 110C1 of the memory semiconductor structure 110C being proximal to the front side 110D1 of the memory semiconductor structure 110D.

In FIG. 13C, the memory stacking pair 12 is flipped upside down so as to be bonded to the memory semiconductor structure 110E by hybrid bonding the bonding layer 130E2 and the bonding layer 130C2. As a result, the back side 110E2 of the memory semiconductor structure 110E is proximal to the back side 110C2 of the memory semiconductor structure 110C. In the following steps, the logic semiconductor structure 120 can be bonded to the memory stacking pair 12 by the similar steps described in FIGS. 7D-7F, and the detail steps are not described herein for brevity.

In the present embodiment, the memory semiconductor structure 110E is stacked between the memory stacking pair 11 and the memory stacking pair 12, and the logic semiconductor structure 120 is stacked on the memory stacking pair 12 in a later stage, therefore, the logic semiconductor structure 120 can be protected from being damaged during the stacking and thinning processes of the memory semiconductor structures 110A, 110B, 110C, and 110D and 110E.

In some embodiments, the semiconductor device comprises N memory stacking pairs and M single memory semiconductor structure, wherein N≥1 and M≥1. The M single memory semiconductor structure can be stacked between two memory stacking pairs (e.g., FIG. 12) or between one memory stacking pair and the logic semiconductor structure (e.g., FIG. 10). In these embodiments, each of the memory stack pairs comprises two memory semiconductor devices stacked in front-to-front manner. Also, the front side of the single memory semiconductor structure is proximal to the back side of one of the memory semiconductor structures in the memory stacking pair. In some embodiments, the stacking methods described in the previous embodiments can be applied to form the semiconductor device that includes N memory stacking pairs and M single memory semiconductor structure. That is, regardless the number of memory stacking pairs and the number of single memory semiconductor structures to be stacked in the semiconductor device, the methods provided in the present disclosure allow the memory semiconductor structures to be stacked properly, and allows the logic semiconductor structure to be stacked in a later or last stage, thereby protecting the logic semiconductor structure from being damaged and reducing the possible yield impact of bonding process.

In summary, the semiconductor devices and the methods for forming the semiconductor devices provided by the embodiments of the present disclosure allow each two memory semiconductor structures to be stacked in a front-to-front manner to form a memory stacking pair, and allow the logic semiconductor structure to be stacked on the memory stacking pairs in a later stage, thereby protecting the logic semiconductor structure from being damaged by the physical stress caused during the stacking and thinning processes of the memory semiconductor structures. As a result, yield of the semiconductor device can be significantly improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods and steps.

What is claimed is:

1. A semiconductor device, comprising:
a first memory stacking pair, comprising
a first memory semiconductor structure having a first front side and a first back side opposite to the first front side; and
a second memory semiconductor structure having a second front side and a second back side opposite to the second front side,
wherein the first memory semiconductor structure is bonded to the second memory semiconductor structure, and the first front side of the first memory semiconductor structure is proximal to the second front side of the second memory semiconductor structure, and the first back side is distal to the second back side.

2. The semiconductor device of claim 1, further comprising:
a logic semiconductor structure having a front side and a back side, wherein the logic semiconductor structure is bonded to the first memory stacking pair, and the front side of the logic semiconductor structure is proximal to the first back side of the first memory semiconductor structure.

3. The semiconductor device of claim 1, further comprising:
a second memory stacking pair, comprising
a third memory semiconductor structure having a third front side and a third back side; and
a fourth memory semiconductor structure having a fourth front side and a fourth back side;
wherein the third memory semiconductor structure is bonded to the fourth memory semiconductor structure, and the third front side of the third memory semiconductor structure is proximal to the fourth front side of the fourth memory semiconductor structure.

4. The semiconductor device of claim 3, wherein the first memory stacking pair is bonded to the second memory stacking pair, and the second back side of the second memory semiconductor structure is proximal to the third back side of the third memory semiconductor structure.

5. The semiconductor device of claim 4, further comprising:
a logic semiconductor structure having a front side and a back side, wherein the logic semiconductor structure is bonded to the first memory stacking pair, and the front side of the logic semiconductor structure is proximal to the first back side of the first memory semiconductor structure.

6. The semiconductor device of claim 1, further comprising:
a fifth memory semiconductor structure having a fifth front side and a fifth back side;
wherein the fifth memory semiconductor structure is bonded to the first memory stacking pair, and the fifth front side of the fifth memory semiconductor structure is proximal to the first back side of the first memory semiconductor structure.

7. The semiconductor device of claim 6, further comprising a logic semiconductor structure having a front side and a back side, wherein the logic semiconductor structure is bonded to the fifth memory semiconductor structure, and the front side of the logic semiconductor structure is proximal to the fifth back side of the fifth memory semiconductor structure.

8. The semiconductor device of claim 6, further comprising a second memory stacking pair, bonded to the fifth back side of the fifth memory semiconductor structure.

9. The semiconductor device of claim 1, wherein:
a circuitry layout of the first memory semiconductor structure is identical to a circuitry layout of the second memory semiconductor structure, and the layout of the first memory semiconductor structure is mirror symmetric.

10. The semiconductor device of claim 1, wherein:
a circuitry layout of the first memory semiconductor structure is a mirror image of a circuitry layout of the second memory semiconductor structure.

11. The semiconductor device of claim 1, wherein: the first stacking memory pair comprises a RDL formed on the first back side of the first memory semiconductor structure.

12. The semiconductor device of claim 1, wherein: the first memory semiconductor structure and the second memory semiconductor structure are dynamic-random-access-memory.

13. A semiconductor device, comprising:
N memory stacking pairs, each of the N memory stacking pairs comprising
a first memory semiconductor structure having a first front side and a first back side opposite to the first front side; and
a second memory semiconductor structure having a second front side and a second back side opposite to the second front side,
wherein N≥1, and the first memory semiconductor structure is bonded to the second memory semiconductor structure with the first front side of the first memory semiconductor structure being proximal to the second front side of the second memory semiconductor structure, and the first back side being distal to the second back side.

14. The semiconductor of the claim 13, wherein: a first memory stacking pair of the N memory stacking pairs is bonded to a second memory stacking pair of the N memory stacking pairs, and a back side of a memory semiconductor structure in the first memory stacking pair is proximal to a back side of a memory semiconductor structure in the second memory stacking pair.

15. The semiconductor of the claim 13, further comprising: M single memory semiconductor structures stacked with the N memory stacking pairs, and M≥1, wherein one of the M single memory semiconductor structures is bonded to one of the N memory stacking pairs, and the one of the M single memory semiconductor structures comprises a substrate and a front side distal to the substrate, wherein the front side of the one of the M single memory semiconductor structures is proximal to a back side of a memory semiconductor structure in the one of the N memory stacking pairs.

16. A method of manufacturing a semiconductor device, comprising:
providing a first memory semiconductor structure having a first front side and a first back side;
providing a second memory semiconductor structure having a second front side and a second back side; and
bonding the first memory semiconductor structure to the second memory semiconductor structure to form a first memory stacking pair, wherein the first front side of the first memory semiconductor structure is proximal to the second front side of the second memory semiconductor structure.

17. The method of claim 16, further comprising:
providing a logic semiconductor structure having a front side and a back side; and
bonding the logic semiconductor structure to the first memory stacking pair, wherein the front side of the logic semiconductor structure is proximal to the first back side of the first memory semiconductor structure.

18. The method of claim 16, further comprising:
providing a third memory semiconductor structure having a third front side and a third back side;
providing a fourth memory semiconductor structure having a fourth front side and a fourth back side; and
bonding the third memory semiconductor structure to the fourth memory semiconductor structure to form a second memory stacking pair, wherein the third front side of the third memory semiconductor structure is proximal to the fourth front side of the fourth memory semiconductor structure; and
bonding the first memory stacking pair to the second memory stacking pair, wherein the second back side of the second memory semiconductor structure is proximal to the third back side of the third memory semiconductor structure.

19. The method of claim 18, wherein the step of bonding the first memory stacking pair to the second memory stacking pair comprises:
thinning a substrate at the second back side of the second memory semiconductor structure;
thinning a substrate at the third back side of the third memory semiconductor structure;
forming a bonding layer over the substrate of the second memory semiconductor structure;
forming a bonding layer over the substrate of the third memory semiconductor structure; and
bonding the bonding layer over the substrate of the second memory semiconductor structure to the bonding layer over the substrate of the third memory semiconductor structure.

20. The method of claim 18, further comprising:
providing a logic semiconductor structure having a front side and a back side; and
bonding the logic semiconductor structure to the first memory stacking pair, after the bonding the first memory stacking pair to the second memory stacking pair.
